(19) United States
(12) Patent Application Publication
(10) Pub. No.: US 2026/0016514 A1
(43) Pub. Date: Jan. 15, 2026

(54) DISTRIBUTED ELECTRIC POWER MEASUREMENT SYSTEM AND ASSOCIATED METHOD

(71) Applicant: Schneider Electric Industries SAS, Rueil-Malmaison (FR)

(72) Inventor: Denis Dodelin, Grenoble (FR)

(73) Assignee: Schneider Electric Industries SAS, Rueil-Malmaison (FR)

(21) Appl. No.: 18/992,671

(22) PCT Filed: Jul. 12, 2023
(86) PCT No.: PCT/EP2023/069323

§ 371 Date: Jan. 9, 2025

(30) Foreign Application Priority Data
Jul. 13, 2022 (FR) FR2207216

(51) Int. Cl. G01R 22/06; G01R 19/10; G01R 19/25

(52) U.S. Cl. CPC G01R 22/063; G01R 19/10; G01R 19/2509; G01R 19/2513

(57) ABSTRACT

A distributed system for measuring electrical power in an electrical installation powered by a cyclical alternating electrical signal, the system including a device for measuring voltages and at least one device for measuring currents suitable for communicating according to a communication protocol. The device for measuring voltages is configured, during a transmission period including a plurality of successive cycles of the electrical signal, to code the samples of voltage, per cycle, to form a codeword and to transmit the codeword to the device(s) for measuring currents. Each device for measuring currents is configured to receive at least two successive communication frames, each frame corresponding to a cycle of the electrical signal; for each frame, to determine and apply a decompression method to obtain N decoded samples of voltage, and to compute a series of power values.

### FIELD OF THE INVENTION

The present invention relates to a distributed system for measuring electrical power in an electrical installation powered by a cyclic alternating electrical signal, and to an associated method for measuring electrical power.

The invention belongs to the field of systems for measuring electrical power in electrical installations.

### BACKGROUND OF THE INVENTION

Power measuring devices, or wattmeters, are known, which are used in various electrical installations to monitor the electrical power consumed by the installation, and to better protect the electrical installation.

More particularly, the invention relates to a distributed system for measuring power, including a device for measuring voltages and at least one device for measuring currents remote from the device for measuring voltages, which are suitable for communicating via a communication protocol, via a radio or wired communication link.

One of the problems that arises in such a system is to limit the electrical consumption of each of the measuring devices, more particularly when same are self-powered.

For example, in a distributed system of measurement comprising a plurality of self-powered device for measuring currents suitable for communicating via a radio communication link, according to a radio communication protocol, e.g. Bluetooth or ZigBee, it has been found that the module which ensures radio communication has a high electrical consumption.

There is then a need to limit the electrical consumption of such devices for measuring currents.

### SUMMARY OF THE INVENTION

To this end, the invention proposes a distributed system for measuring electrical power in an electrical installation powered by a cyclic alternating electrical signal, the system comprising a device for measuring voltages and at least one device for measuring currents remote from the device for measuring voltages, the device for measuring voltages being configured to acquire a predetermined number N of samples of voltage per cycle of said electrical signal, each device for measuring currents being configured to acquire N samples of current per cycle of said electrical signal, the device for measuring voltages and the or each device for measuring currents being suitable for communicating according to a communication protocol.

The system is such that the device for measuring voltages is configured, during a transmission period comprising a plurality of successive cycles of said electrical signal,
for each cycle, to code the samples of voltage to form a codeword and transmit said codeword in a communication frame of said communication protocol to the or each device for measuring currents,
   the or each device for measuring currents is configured:
to receive at least two successive communication frames, each communication frame corresponding to one cycle of the electrical signal,
for each frame, to determine a decompression method to be applied and apply that decompression method to obtain N decoded samples of voltage for the corresponding cycle,
to compute a series of N power values for the corresponding cycle using the measured samples of current and the decoded samples of voltage.

Advantageously, the distributed system for measuring electrical power uses a compression of the samples of voltage transmitted to the device(s) for measuring currents, per cycle of the electrical signal, which makes it possible to reduce the effective communication time, and hence reduce the electrical consumption of the device for measuring currents.

The distributed system for measuring electrical power according to the invention can further have one or a plurality of the features below, taken independently or according to all technically feasible combinations.

The plurality of successive cycles includes an initial cycle and subsequent cycles, and the device for measuring voltages is configured to apply, for the samples of voltage of each current cycle distinct from the initial cycle, a differential compression implementing for at least two successive cycles, a computation of differences, sample by sample, between samples of the current cycle and samples of a preceding cycle, a computation of a number P of bytes to code said differences and the formation of a codeword of P bytes,

the or each device for measuring currents is configured:
to extract a codeword from each frame, and determine a number of bytes received and according to said number of bytes received, determine the decompression method to be applied.

The differential compression uses, for a series including a successive first cycle and second cycle, for the compression of the samples of said second cycle, a computation of differences, sample by sample, between samples of the second cycle and samples of the first cycle, to form a series of differential values to be coded.

The differential compression uses, for a series including a first cycle, a second cycle and a third cycle, for the compression of the samples of said third cycle,
a first computation of differences, sample by sample, between samples of the third cycle and samples of the second cycle to form a series of first differences,
a second computation of differences, sample by sample, between samples of the second cycle and samples of the first cycle to form a series of second differences,
a computation of a difference between the series of first differences and the series of second differences to form a series of difference values to be coded.

The device for measuring voltages is further configured to determine a minimum and a maximum of said series of difference values to be coded, and then a number B of bits to code each of said series of difference values according to said minimum and maximum.

The device for measuring voltages is further configured to determine a gain value according to said minimum and maximum of said series of difference values to be coded, and to code said gain value.

A coding table indicating for each interval of a plurality of intervals of difference values, the number of bits B for coding each of the series of difference values to be used for said interval, and a number P of associated coding bytes, is previously stored by said device for measuring voltages and by the or each device for measuring currents.

The or each device for measuring currents, in order to determine a decompression method to be applied, determines whether the number of bytes received belongs to said coding table, and in the event of a positive response, determines the number B of bits used to code each value of the series of difference values.

In the initial cycle, each sample of voltage having an amplitude value and a phase value, the codeword is formed by coding said amplitude and phase values.

According to another aspect, the invention relates to a method for measuring electrical power implemented by a distributed electrical power measuring system as briefly described hereinabove. The method includes steps implemented by an electronic computation unit of the device for measuring voltages, including, during a transmission period including a plurality of successive cycles of said electrical signal, a coding of the samples of voltage to form a codeword and a transmission of said codeword in a communication frame of said communication protocol to the or each device for measuring currents,

and includes steps, implemented by an electronic computing unit of at least one device for measuring currents,
of reception of at least two successive communication frames, each communication frame corresponding to one cycle of the electrical signal,
for each frame, of determination of a decompression method to be applied and application of said decompression method to obtain N decoded samples of voltage for the corresponding cycle,
of computation of a series of N power values for the corresponding cycle using measured samples of current and decoded samples of voltage.

According to another aspect, the invention relates to a software program including a first software program including code instructions and a second software program including code instructions, which, when the first software program is executed on a device for measuring voltages and the second software program is executed on at least one device for measuring currents, implements a method for measuring electrical power in an electrical installation as briefly described hereinabove.

### BRIEF DESCRIPTION OF THE DRAWINGS

Other features and advantages of the invention will be clear from the description thereof which is given below as a non-limiting example, with reference to the enclosed figures, among which:

FIG. 1 schematically represents a distributed system for measuring electrical power according to the invention;

FIG. 2 is a synoptic diagram of the main steps used by a device for measuring voltages according to a first embodiment;

FIG. 3 is a synoptic diagram of the main steps used by a device for measuring currents according to a first embodiment;

FIG. 4 is a synoptic diagram of steps of a second embodiment, different from the steps of the first embodiment, used by a device for measuring voltages;

FIG. 5 is a synoptic diagram of steps of a second embodiment, different from the steps of the first embodiment, used by a device for measuring currents.

### DETAILED DESCRIPTION OF EMBODIMENTS

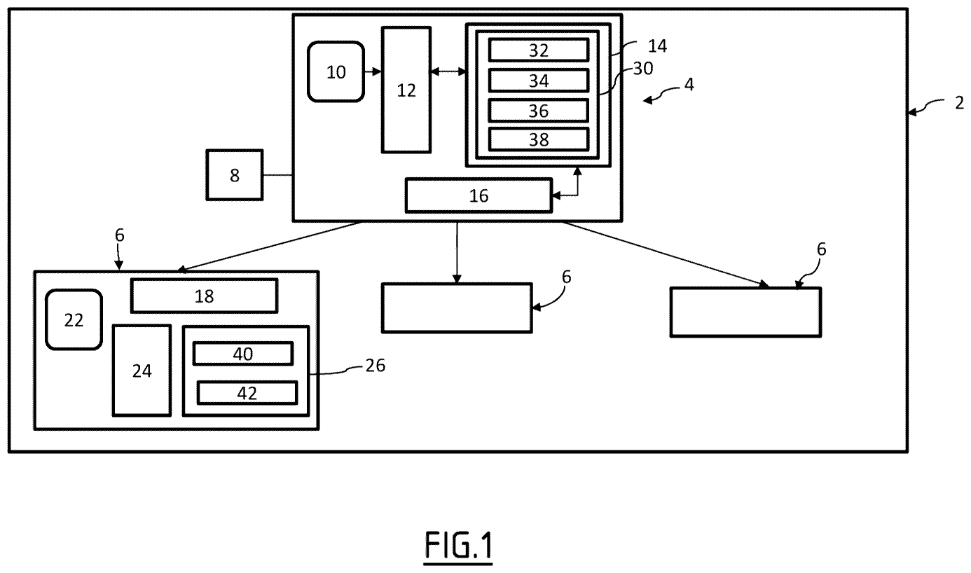

FIG. 1 schematically represents an embodiment of a distributed system for measuring electrical power 2 suitable for providing measurements of electrical power in an electrical installation (not shown) powered by a cyclic alternating electrical signal.

The system 2 includes a device for measuring voltages 4 and a plurality of devices for measuring currents 6, which are distant from the device for measuring voltages 4, the devices 4 and 6 being digital devices for the electronic measurement of voltages and currents.

For example, the device for measuring voltages 4 is placed at one location in the electrical installation, and the device for measuring currents 6 are distributed at a plurality of other locations in the electrical installation.

The example of FIG. 1 comprises three devices for measuring currents 6, but in practice the number of devices for measuring currents 6 is arbitrary. Only one of the devices for measuring currents 6 is shown in detail in FIG. 1, with the proviso that all the devices for measuring currents 6 have a similar structure and functions.

The device for measuring voltages 4 is supplied with electrical energy by a source of electrical energy 8, shown schematically.

The source of electrical energy 8 has been schematically shown outside the device for measuring voltages 4, but according to alternative embodiments, the source of electrical energy 8 is placed inside the device for measuring voltages 4.

In one embodiment, the source of electrical energy 8 is a 24 V power supply.

According to a variant, the source of electrical energy 8 is the electrical distribution network the voltage of which is measured.

In another variant, the source of electrical energy 8 is a battery, e.g. placed inside the device for measuring voltages 4.

The device for measuring voltages 4 further includes a voltage sensor 10 suitable for taking voltage measurements on command or at set time intervals.

For example, the voltage sensor 10 is suitable for measuring voltage values of a cyclic alternating electrical signal.

In a known manner, such an electrical signal is substantially periodic, e.g. substantially sinusoidal, and includes cycles, each cycle corresponding to a sinusoidal period. According to variants, the electrical signal is a triangle or square signal.

For example, the voltage sensor 10 is configured to acquire a predetermined number N of samples of voltage per cycle of said electrical signal.

The number N is chosen, e.g. N=40 per cycle of the electrical signal, in order to comply with the requirements of the performance standards of digital electronic measuring devices, more particularly the standard IEC 61557-12.

The device for measuring voltages 4 further includes an electronic memory unit 12, an electronic computation unit 14, e.g. a processor or a microcontroller, and a communication module 16.

In one embodiment, the measured samples of voltage are time-stamped and stored in the electronic memory unit 12 with associated time-stamp information.

In one embodiment, the communication module 16 is a radio communication module suitable for communicating, in transmission and in reception, according to a given radio communication protocol.

The radio communication protocol is e.g. Bluetooth, Bluetooth Low Energy (BLE), or ZigBee.

In another embodiment, the communication module 16 makes communication possible according to a wired protocol, e.g. Ethernet, Modbus, CAN.

According to a variant, the device 4 includes a plurality of communication modules 16 configured to communicate according to radio and wired communication protocols.

Each device for measuring currents 6 further includes a communication module 18, as well as an electronic memory unit 24 and an electronic computation unit 26, e.g. a processor or a microcontroller.

The communication module 18 is suitable for communicating according to the same communication protocol, radio and/or wired, as the communication module 16.

Thereby, the device for measuring voltages 4 is configured to communicate with each device for measuring voltages 6 according to the chosen communication protocol.

Each device for measuring currents 6 further includes a current sensor 22 suitable for taking current measurements at set time intervals, or in other words with set time sampling steps.

Each device for measuring currents 6 is a device that is self-supplied with electrical energy via the current sensor 22.

For example, the current sensor 22 is suitable for measuring current values of a cyclic alternating electrical signal.

Preferably, the current sensor 22 is configured to acquire N samples of current per cycle of said electrical signal, e.g. N=40.

In other words, the same number N of voltage and samples of current is obtained by the device for measuring voltages and by each device for measuring currents, respectively.

The system 2 is configured to transmit measured samples of voltage, which are preferably time-stamped, by the device for measuring voltages 4 to the device for measuring currents 6.

In one embodiment, the measured samples of voltage are transmitted at each cycle of the electrical signal.

Each of the devices for measuring currents 6 furthermore acquires samples of current per cycle, and thereby a distributed computation of voltage measurement per cycle of the electrical signal is performed, from the samples of voltage received and the samples of current acquired.

In order to save the electrical energy consumed by the devices for measuring voltages and currents, the system 2 is configured to perform compression of the samples of voltage before they are transmitted by the device for measuring voltages 4, and decompression by each device for measuring currents 6.

Thereby, advantageously, the quantity of data transmitted by the device for measuring voltages 4 and received by the or each device for measuring currents 6 is reduced, which makes it possible to reduce the communication time for the respective communication modules 16 and 18, the electrical consumption of which is greater than the electrical consumption of the computing units 14 and 26, which are e.g. computation processors such as a CPU (Central Processing Unit) or a MPU (Microprocessing Unit).

The electronic computation unit 14 is configured to execute a coding module 30 for coding, for each cycle of the electrical signal, the samples of voltage into a codeword. The samples of voltage per cycle are stored in the electronic memory unit 12 for at least two successive cycles.

In one embodiment, samples of voltage reconstituted by decoding, for at least one cycle preceding a current cycle, are stored in the electronic memory unit 12.

The coding module 30 uses, starting from the second cycle of a transmission period of chosen duration, for a successive first cycle and second cycle, a module 32 for computing differences, sample by sample, between samples of the second cycle and samples of the first cycle, to form a series of difference values to be coded.

According to a variant, the module 32 uses a computation of differences of differences (or double difference) to form a series of difference values to be coded, over a series of three cycles including a first cycle, and a second cycle and a third cycle, respectively, as described in greater detail hereinafter.

The module 30 also uses a module 34 for determining a minimum and a maximum of the series of difference values to be coded, then a number B of bits to code each value of the series of difference values according to said minimum and maximum. The module 34 further computes a number P of bytes for coding the samples of the current cycle.

In one embodiment, the number P is obtained by multiplying the number B of bits by the number N of samples of voltage per cycle.

According to one variant, the number P is furthermore dependent on a gain value to be coded.

Finally, the module 30 implements a module 36 for coding the series of difference values into a codeword of P bits. The codeword is transmitted to the communication module 16 for transmission in a communication frame according to the chosen communication protocol.

In one embodiment, the module 30 also uses a decoding module 38 which computes the values of samples of voltage reconstituted by decoding, analogous to the samples of voltage decoded by the device for measuring currents.

In one embodiment, the modules 32, 34, 36 and 38 each consist of a first software.

In a variant (not shown), the modules 32, 34, 36, and 38 are each produced in the form of a programmable logic component, such as an FPGA (Field Programmable Gate Array), or further of a dedicated integrated circuit, such as an ASIC (Application Specific Integrated Circuit).

The first software is furthermore apt to being saved in the form of an executable program including software instructions, on a non-volatile medium (not shown) readable by a programmable electronic device.

Each device for measuring currents 6 receives the codewords representative of the samples of voltage per cycle.

The electronic computation unit 26 is configured to execute a decompression module 40 which determines, for each codeword received, a decompression method to be applied as a function of the number of bytes on which the codeword received is coded, and applies the decompression method chosen to obtain N decoded samples of voltage for the current cycle.

The electronic computation unit 26 is also configured to execute a module 42 for power computation which computes a series of power values from the samples of current acquired by the sensor 22 and the decoded samples of voltage.

In one embodiment, the modules 40, 42 each consist of a second software.

In a variant (not shown), the modules 40, 42 each consist of a programmable logic component, such as an FPGA (Field Programmable Gate Array), or further of a dedicated integrated circuit, such as an ASIC (Application Specific Integrated Circuit).

The second software is furthermore apt to be saved in the form of an executable program including software instructions, on a non-volatile medium (not shown), readable by a programmable electronic device.

The first software and the second software are suitable for cooperating and form a software (or computer program) implementing a distributed method of measuring electrical power.

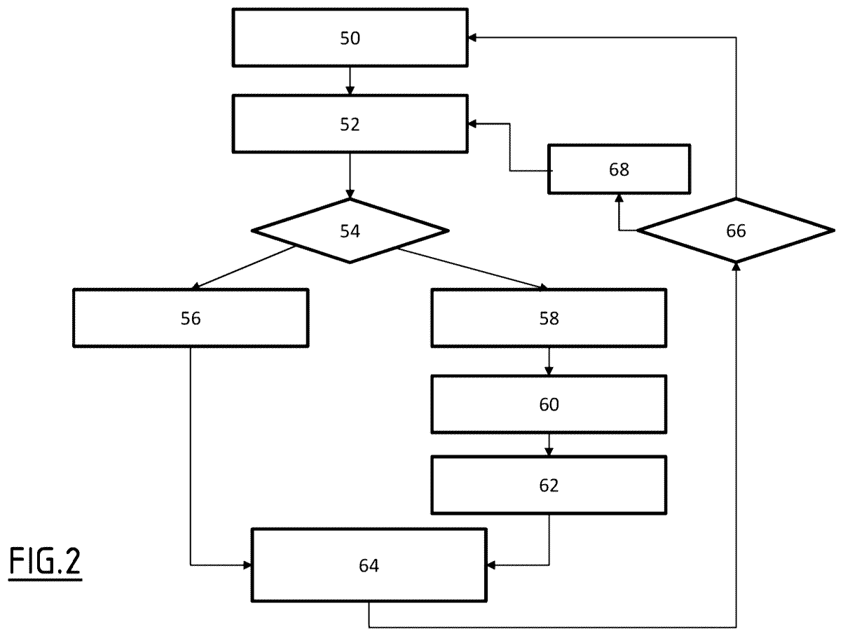

FIG. 2 is a synoptic diagram of the main steps of a distributed method for measuring electrical power, implemented by a device for measuring voltage in a first embodiment.

The method comprises an initialization 50, during which an index i of current cycle of a transmission period is initialized to 0.

The index 0 corresponds to a first cycle, also called the initial cycle, of the transmission period.

The transmission period has a chosen duration, e.g. equal to 1 second. Thereby, for an electrical signal of frequency equal to 50 Hz, a transmission period includes 50 cycles.

The method comprises a step 52 of acquisition of N samples of voltage for the current cycle, and a storage of the samples of voltage.

The number N of samples per cycle is predetermined, e.g. N=40.

The time sampling step of the voltage sensor is adjusted to obtain N samples per cycle.

According to one variant, the time sampling step of the voltage sensor is different from N, and an interpolation computation is used during step 52 so as to obtain N samples per cycle.

The method then includes a test step 54 for determining whether the current cycle is the first cycle (or initial cycle) of the transmission period.

To carry out the test, the value of the cycle index i is compared to the initialization value, thus to zero in the present embodiment.

In the event of a positive response, i.e. if the cycle index i is equal to zero, a specific coding method of the samples of voltage of the first cycle is applied to the step of coding the samples 56.

For example, since the electrical signal is a sinusoidal signal, the amplitude and phase values are coded for each sample of voltage. In one embodiment, the amplitude value is coded on 2 bytes and the phase is coded on 2 bytes.

In the event of a negative response to the test step 54, the current cycle is the second cycle or a subsequent cycle.

The method comprises a step 58 of differential compression, which uses a computation of the differences, sample by sample, between the samples of voltage of the current cycle of index i and the samples of voltage of the cycle of index i-1, previously stored, to form a series of difference values to be coded.

If a series of N samples of cycle index i is denoted by

$$\{ {S}_{1}^{i} , … ; , {S}_{j}^{i} , … , {S}_{N}^{i} \} ,$$

the series of difference values is denoted by:

$$D ( i , i - 1 ) = \{ {S}_{1}^{i} - {S}_{1}^{i - 1} , … , {S}_{N}^{i} - {S}_{N}^{i - 1} \} .$$

In one embodiment, the difference is taken between the amplitude values of the samples of voltage of the current cycle of index i and the voltage amplitude values of the preceding cycle which are reconstituted by decoding, and stored at each cycle.

The reconstitution (or decoding) is performed according to the computation described hereinafter with reference to the decoding step 82.

Then, during a step 60 of determination of a number B of bits to be used to code each difference value, the method determines a minimum and a maximum of the series of difference values to be coded. The number B of bits for coding each value of the series of difference values is deduced therefrom.

For example, a coding table associating a number B of bits with an interval of difference values is used. In other words, the coding interval chosen is the interval to which the minimum and maximum of the series of difference values to be coded belong.

In one embodiment, the table 1 is used.

TABLE 1
coding intervals and number B of bits
per difference value to be coded

| Minimum | Maximum | B | P |
|---|---|---|---|
| −1 | 0 | 1 | 5 |
| −2 | 1 | 2 | 10 |
| −4 | 3 | 3 | 15 |
| −8 | 7 | 4 | 20 |
| −16 | 15 | 5 | 25 |
| −32 | 31 | 6 | 30 |
| −64 | 63 | 7 | 35 |
| −128 | 127 | 8 | 40 |

In table 1, the number P of bytes used to form a codeword per cycle is also indicated.

It can be seen that P=B×N/8, with N=40 in the present example.

It is understood that table 1 is given as an example, and that other tables could be used, e.g. with minimum and maximum values shifted by a shift of +1. Such a shift preserves an average centered on 0 for each interval.

In one embodiment, if the minimum Vₘᵢₙ is less than −128 or if the maximum Vₘₐₓ is greater than 127, the coding is modified by adding a gain value G, which is additionally coded, the gain G being e.g. the divider which makes it possible to bring each of the respective values Vₘᵢₙ and Vₘₐₓ into the considered interval:

$$\frac{{V}_{max}}{G} ⊂ [ - 128 , 127 ] and \frac{{V}_{min}}{G} ⊂ [ - 128 , 127 ]$$

Each of the difference values to be coded is then divided by G, which induces a slight loss of precision.

For example, the gain value is coded on an additional byte, added to the P=40 bytes of the last interval [−128, 127]. In such case, the coding table is enriched with a number P of bytes equal to 41 for the coding with gain.

Then, during a coding step 62, each difference value is coded on B bits, e.g. on the basis of a predetermined coding table, e.g. the table 1 given hereinabove.

The method finally includes a step 64 of shaping the codeword in a communication frame according to the chosen communication protocol, and transmission of the codeword.

For example, the communication protocol chosen is the Bluetooth protocol or the ZigBee protocol.

Step 64 is followed by a step 66 consisting in verifying whether all the cycles of the transmission period have been processed. For example, the cycle index i is compared with a predetermined maximum cycle index value per transmission period, and it is verified during step 66 whether the current cycle index is equal to the predetermined maximum value.

Step 66 is followed by step 68 if the response is negative, during which the current cycle index is incremented by 1 for the processing of the next cycle. Step 68 is followed by step 52 previously described.

If the response is positive, step 66 is followed by step 50 previously described.

In other words, when the last cycle of a transmission period is processed, the method returns to step 50 for a subsequent transmission period.

Advantageously, as a result, it is possible to code the samples of voltage of the initial cycle of the new transmission period, and consequently to obtain a more efficient differential coding.

It should be noted that in addition to the series of difference values per cycle, timestamp information is transmitted for the synchronization by the device for measuring currents, more particularly for a synchronization between clocks of the device for measuring voltages and each device for measuring currents. For example, the timestamp information is also compressed, e.g. by a double difference compression. Any known synchronization method can be implemented to achieve such synchronization.

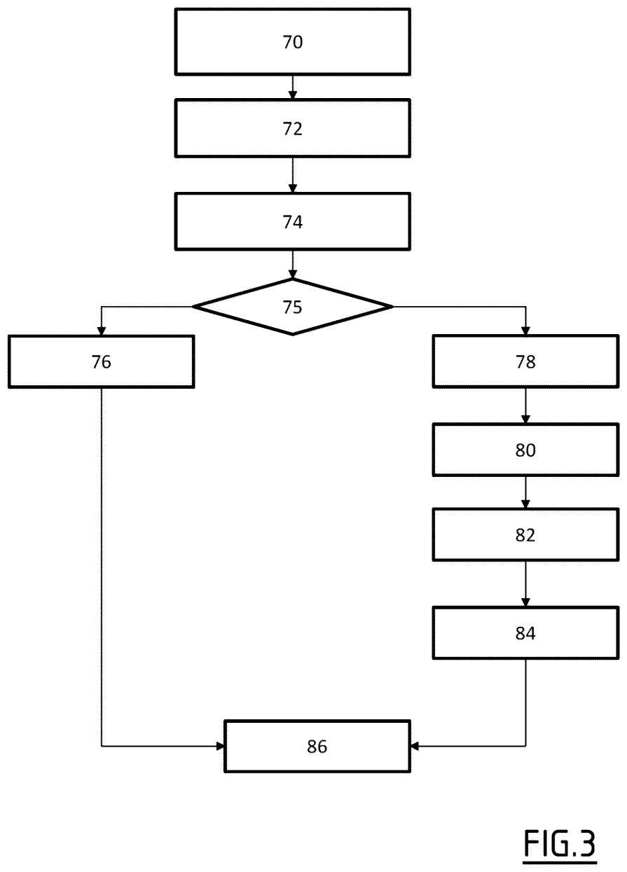

FIG. 3 is a synoptic diagram of the main steps of a distributed method for measuring electrical power, implemented by a device for measuring currents, in a first embodiment.

In the first embodiment, each device for measuring currents receives frames including codewords, each codeword including data representative of the samples of voltage per cycle, obtained by the method steps described with reference to FIG. 2.

The method includes a step 70 of reception of communication frames, each frame including a codeword corresponding to a cycle of electrical signal, and a step 72 of storage of the extracted codewords.

Then, during a step 74 of determination of the number of bytes, the number P of bytes on which the codeword extracted from the current frame is represented is determined.

Depending on the number P of bytes, the method determines a decompression method to obtain, from the codeword, N decoded samples of voltage for the corresponding cycle.

During a test step 75, it is verified whether the number P belongs to a coding table used during coding, e.g. to the table 1, as described with reference to FIG. 2.

If the number P does not belong to a coding table used during coding (negative response during step 75), it is deduced that the current cycle is a first cycle (or initial cycle) of a transmission period.

The amplitude and phase values of the N samples of voltage of the first cycle of a transmission period are decoded and stored during a step 76.

The decoding is a specific decoding corresponding to the specific coding method of the samples of the first cycle used during step 56.

If the number P is a number belonging to a coding table used, the coding table being shared with the device for measuring voltages which transmits the coded samples of voltage, then the number B of bits used to code each difference value is deduced, during a step 78.

In a variant, without using a stored coding table, during step 75 it is verified whether the number P of bytes multiplied by 8 and divided by the number N of samples per cycle is an integer between 1 and 8, and the number being the number B of bits per difference value.

Step 78 is followed by a decoding step 80 to obtain N decoded difference values, which are stored.

For example, the received codeword is divided into N words of B bits, each word of B bits representing a difference value, according to the coding table used for coding.

Then, during a decoding step 82, decoded samples of voltage are obtained from decoded difference values and sample of voltage values previously stored for a previous cycle.

For example, if the current cycle has an associated index i, the decoded and previously stored values of samples of voltage for the cycle of index i-1 are used.

In other words, if D(i, i−1)={Δ₁, . . . , Δ_{N}} denotes the series of decoded difference values, and

$$\{ {V}_{1}^{i - 1} , … , {V}_{N}^{i - 1} \}$$

denotes a series of N decoded samples of voltage for the cycle (i-1), the values of samples are obtained by the formula:

$${V}_{j}^{i} = {V}_{j}^{i - 1} + {Δ}_{j}$$

The N values of samples of voltage decoded for the current cycle of index i are also stored during a storage step 84.

Steps 76 and 84 are followed by a step 86 of computing N power values from the N decoded samples of voltage and the N corresponding samples of current acquired by the current sensor of the device for measuring currents.

In addition to the steps of the method described hereinabove, having the goal of obtaining decoded samples of voltage to perform the computation of the power values, the method includes a synchronization according to received timestamp information, by any suitable method.

Steps 70 to 86 are repeated for each new frame received.

Thereby, upon reception of a frame corresponding to a first cycle of a transmission period, series of N decoded samples of voltage are obtained for each successive cycle.

The first embodiment described with reference to FIGS. 2 and 3 implements a compression by difference between samples of successive cycles.

According to a second embodiment, in a variant, the distributed method for measuring electrical power uses a compression by differences of differences (or double differences).

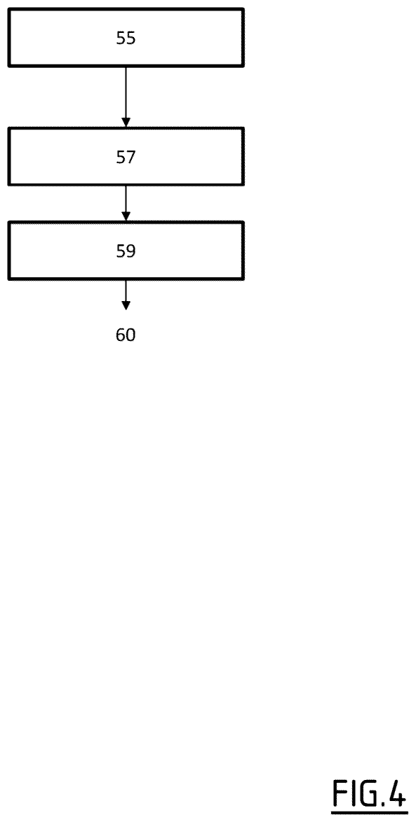

Steps of the second embodiment, different from the steps of the first embodiment, implemented by the device for measuring voltages, are illustrated with reference to FIG. 4.

In such embodiment, the test 54 furthermore serves to determine whether the current cycle is a third cycle or a following cycle of the transmission period.

The first cycle (initial cycle) is coded in a manner analogous to the first embodiment, and the second cycle is coded by (simple) difference according to the method described with reference to FIG. 2.

Starting from the third cycle of a transmission period, step 54 is followed by processing for a series including a first cycle of index i-2, a second cycle of index i-1 and a third cycle (current cycle) of index i.

The processing includes a first computation of differences (step 55), sample by sample, between samples from the third cycle and samples from the second cycle, so as to form a series of first differences:

$${D}_{1} ( i , i - 1 ) = \{ {S}_{1}^{i} - {S}_{1}^{i - 1} , … , {S}_{N}^{i} - {S}_{N}^{i - 1} \}$$

In other words, the differences between the samples of the cycle of index i and the samples of the cycle of index (i-1) are computed.

In one embodiment, the samples of the second cycle are reconstituted by decoding.

In addition, a second computation of differences (step 57) is performed, sample by sample, between samples of the second cycle of index (i-1) and samples of the first cycle, of index (i-2), so as to form a series of second differences:

$${D}_{2} ( i - 1 , i - 2 ) = \{ {S}_{1}^{i - 1} - {S}_{1}^{i - 2} , … , {S}_{N}^{i - 1} - {S}_{N}^{i - 2} \}$$

In one embodiment, the samples of the first cycle are reconstituted by decoding.

According to a variant, the differences, computed during the first difference computation, sample by sample, between the samples of a current cycle and the samples of a preceding cycle are stored at each iteration.

Step 57 of second computation of the differences is replaced by a step of reading in memory the differences stored during the preceding step.

Step 59 then uses a computation of a difference between the series of first differences and the series of second differences to form a series of difference values to be coded:

$$DD ( i - 2 , i - 1 , i ) = {D}_{2} ( i - 1 , i - 2 ) - {D}_{1} ( i , i - 1 )$$

Step 59 is followed by step 60 of determining a number B of bits to be used to code each difference value, described beforehand with reference to FIG. 2.

Advantageously, in the second embodiment, the difference values to be coded are differences of differences, which serve to increase the compression level.

For the second embodiment, each device for measuring currents uses a corresponding decompression method, for a series of cycles including a first, a second and a third successive cycle, of respective indices i-2, i-1 and i.

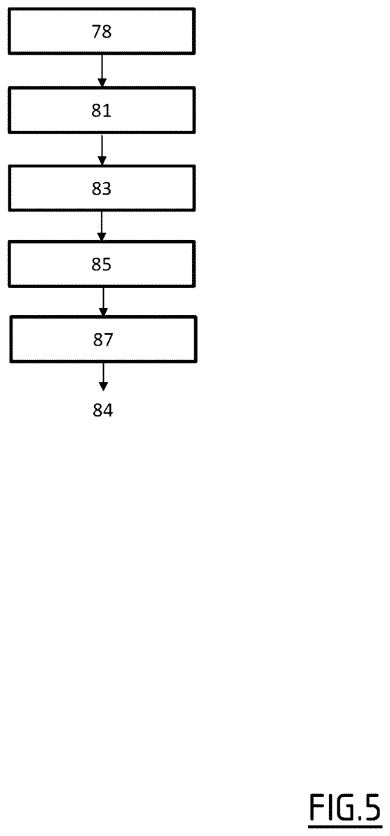

The specific steps of the second embodiment, implemented by a device for measuring currents, are illustrated in the synoptic diagram of FIG. 5.

For a current cycle i, the method implements, after the step 78 previously described, a decoding step 81 to obtain N decoded difference values corresponding to the differences DD(i-2,i-1,i), respectively.

The method comprises a following step 83 of obtaining the difference values between cycle of index (i-1) and cycle of index (i-2), previously decoded and stored, and a step 85 of computation of the decoded difference values between cycle of index i and cycle of index (i-1):

$${D}_{1} ( i , i - 1 ) = {D}_{2} ( i - 1 , i - 2 ) - DD ( i - 2 , i - 1 , i )$$

The decoded difference values computed during step 85 are also stored during said step, for use in a subsequent step.

Then, the method comprises a computation 87 of the decoded samples of voltage for the current cycle of index i from the decoded difference values DD(i, i-1) and the decoded and stored sample of voltage values for the cycle of index (i-1).

The samples of voltage decoded for the current cycle of index i are stored during the storage step 84 previously described.

Advantageously, the distributed method for power computation implements a compression/decompression which serves to obtain a good compression level, including in the event of fluctuations in the electrical signal, and consequently to reduce the electrical consumption of the various devices used.

Advantageously, the differential compression or the double difference compression used is simple and serves to reduces the computational load.

1. A distributed system for measuring electrical power in an electrical installation powered by a cyclical alternating electrical signal, the system including a device for measuring voltages and at least one device for measuring currents remote from the device for measuring voltages,
the device for measuring voltages being configured to acquire a predetermined number N of samples of voltage per cycle of said electrical signal,
each device for measuring currents being configured to acquire N samples of current per cycle of said electrical signal,
the device for measuring voltages and the or each device for measuring currents being suitable for communicating according to a communication protocol,
the system being characterized in that:
the device for measuring voltages is configured, during a transmission period including a plurality of successive cycles of said electrical signal,
for each cycle, to code the samples of voltage to form a codeword and to transmit said codeword in a communication frame of said communication protocol to the or each device for measuring currents,
the or each device for measuring currents is configured:
to receive at least two successive communication frames, each communication frame corresponding to one cycle of the electrical signal,
for each frame, to determine a decompression method to be applied and apply that decompression method to obtain N decoded samples of voltage for the corresponding cycle,
to compute a series of N power values for the corresponding cycle using the measured samples of current and the decoded samples of voltage.

2. The system according to claim 1, said plurality of successive cycles including an initial cycle and subsequent cycles, wherein the device for measuring voltages is configured to apply, for the samples of voltage of each current cycle distinct from the initial cycle, a differential compression implementing for at least two successive cycles, a computation of differences, sample by sample, between samples of the current cycle and samples of a preceding cycle, a computation of a number P of bytes to code said differences and the formation of a codeword of P bytes;
the or each device for measuring currents is configured:
to extract a codeword from each frame, and determine a number of bytes received and according to said number of bytes received, to determine the decompression method to be applied.

3. The system according to claim 2, wherein the differential compression implements, for a series having a successive first cycle and second successive cycle, for the compression of the samples of said second cycle, a computation of differences, sample by sample, between samples of the second cycle and samples of the first cycle, so as to form a series of difference values to be coded.

4. The system according to claim 2, wherein the differential compression implements, for a series including a successive first cycle, second cycle and third cycle, for the compression of the samples of said third cycle,
a first computation of differences, sample by sample, between samples of the third cycle and samples of the second cycle to form a series of first differences,
a second computation of differences, sample by sample, between samples of the second cycle and samples of the first cycle to form a series of second differences,
a computation of a difference between the series of first differences and the series of second differences to form a series of difference values to be coded.

5. The system according to claim 2, wherein the device for measuring voltages is further configured to determine a minimum and a maximum of said series of difference values to be coded, and then a number B of bits to code each of said series of difference values according to said minimum and maximum.

6. The system according to claim 5, wherein the device for measuring voltages is further configured to determine a gain value according to said minimum and maximum of said series of difference values to be coded, and to code said gain value.

7. The system according to claim 5, wherein a coding table indicating for each interval of a plurality of intervals of difference values, the number of bits B for coding each of the series of difference values to be used for said interval, and a number P of associated coding bytes, is previously stored by said device for measuring voltages and by the or each device for measuring currents.

8. The system according to claim 7, wherein the or each device for measuring currents, for determining a decompression method to be applied, determines whether the number of bytes received belongs to said coding table, and in the event of a positive response, determines the number B of bits used to code each of the series of difference values.

9. The system according to claim 2, wherein for the initial cycle, each sample of voltage having an amplitude value and a phase value, the codeword being formed by coding said amplitude and phase values.

10. A distributed method of measuring electrical power in an electrical installation, implemented by a distributed system for measuring electrical power according to claim 1, including steps implemented by an electronic computing unit of the device for measuring voltages, including, during a transmission period including a plurality of successive cycles of said electrical signal, a coding of samples of voltage to form a codeword and a transmission of said codeword in a communication frame of said communication protocol to the or each device for measuring currents,
and including steps, implemented by an electronic computing unit of at least one device for measuring currents:
of reception of at least two successive communication frames, each communication frame corresponding to one cycle of the electrical signal,
for each frame, of the determination of a decompression method to be applied and application of said decompression method to obtain N decoded samples of voltage for the corresponding cycle,
of computation of a series of N power values for the corresponding cycle using the measured samples of current and the decoded samples of voltage.

11. A non-transitory computer-readable medium comprising a software program stored thereon, the software program including a first software program including code instructions and a second software program including code instructions, which, when the first software program is executed on a device for measuring voltages and the second software program is executed on at least one device for measuring currents, causes the method for measuring electrical power in an electrical installation according to claim 10 to be implemented.
